(19) United States
(12) Patent Application Publication
(10) Pub. No.: US 2021/0242876 A1
(43) Pub. Date: Aug. 5, 2021

(54) FLUCTUATION SUPPRESSION CIRCUIT

(71) Applicant: DENSO CORPORATION, Kariya-city (JP)

(72) Inventor: Kazutaka HONDA, Kariya-city (JP)

(21) Appl. No.: 17/238,748

(22) Filed: Apr. 23, 2021

Related U.S. Application Data
(63) Continuation of application No. PCT/JP2019/042361, filed on Oct. 29, 2019.

(30) Foreign Application Priority Data
Nov. 29, 2018 (JP) 2018-223560

(51) Int. Cl. H03M 1/08

(52) U.S. Cl. CPC H03M 1/0863

(57) ABSTRACT

A fluctuation suppression circuit suppresses fluctuation of a reference voltage supplied to a switched capacitor circuit having a differential configuration. The switched capacitor circuit includes an input capacitor for charging an input voltage and a reference capacitor for charging the reference voltage. The input capacitor and the reference capacitor are separately disposed. The fluctuation suppression circuit includes an electric charge supply circuit. The electric charge supply circuit generates an offset electric charge by adopting a predetermined offset voltage, for offsetting a charged or discharged electric charge generated in the switched capacitor circuit, and supplies the offset electric charge to two reference input nodes, which are supplied with the reference voltage, in the switched capacitor circuit.

### CROSS REFERENCE TO RELATED APPLICATIONS

The present application is a continuation application of International Patent Application No. PCT/JP2019/042361 filed on Oct. 29, 2019, which designated the U.S. and claims the benefit of priority from Japanese Patent Application No. 2018-223560 filed on Nov. 29, 2018. The entire disclosures of all of the above applications are incorporated herein by reference.

### TECHNICAL FIELD

The present disclosure relates to a fluctuation suppression circuit.

### BACKGROUND

There has been known a switched capacitor circuit with a differential configuration. The switched capacitor circuit is supplied with a reference voltage.

### SUMMARY

The present disclosure describes a fluctuation suppression circuit that suppresses the fluctuation of a reference voltage supplied to a switched capacitor circuit having a differential configuration, and further describes the fluctuation suppression circuit including an electric charge supply circuit for generating an offset electric charge to offset a charged or discharged electric charge generated in the switched capacitor circuit.

### BRIEF DESCRIPTION OF DRAWINGS

Objects, features and advantages of the present disclosure will become more apparent from the following detailed description made with reference to the accompanying drawings. In the drawings:

FIG. 1 schematically illustrates the configuration of an integrator and the configuration of a fluctuation suppression circuit according to a first embodiment;

FIG. 2 is a timing chart that illustrates an operation of each device in the first embodiment;

FIG. 3 illustrates the effect of enhancing responsiveness of settling according to the first embodiment;

FIG. 4 schematically illustrates the configuration of an integrator and the configuration of a fluctuation suppression circuit according to a second embodiment;

FIG. 5 is a timing chart that illustrates an operation of each device in the second embodiment;

FIG. 6 schematically illustrates the configuration of an integrator and the configuration of a fluctuation suppression circuit according to a third embodiment;

FIG. 7 is a timing chart that illustrates an operation of each device in the third embodiment;

FIG. 8 schematically illustrates the configuration of an integrator and the configuration of a fluctuation suppression circuit according to a fourth embodiment; and

FIG. 9 schematically illustrates the configuration of an integrator and the configuration of a fluctuation suppression circuit according to a fifth embodiment.

### DETAILED DESCRIPTION

In an analog-to-digital converter (A/D converter), a level shift circuit or the like having a switched capacitor circuit adopting a reference voltage, in a situation the reference voltage transiently fluctuates through charging and discharging a capacitor, it may be difficult to have a high-speed operation. Additionally, the precision may deteriorate in, for example, a multichannel device. As a countermeasure against the above-mentioned difficulties, for example, a decoupling capacitor may be added for widening the bandwidth of the amplifier. However, a consumption current may increase through widening the bandwidth of the amplifier, and the number of terminals and the cost for additional components may increase through adding the decoupling capacitor.

A variety of techniques for suppressing transient fluctuation of a reference voltage in an analog-to-digital converter (A/D converter), a level shift circuit or the like have been introduced. A comparative example adopts a configuration of suppressing the conduction of noise caused by the fluctuation of a reference voltage generated at a power supply, but does not adopt a configuration of suppressing the fluctuation of the reference voltage supplied to a circuit being a supply target. Therefore, in the comparative example, the fluctuation of the reference voltage received at the circuit being the supply target may not be suppressed, and the noise caused by the fluctuation may be generated.

According to an aspect of the present disclosure, a fluctuation suppression circuit suppress the fluctuation of a reference voltage supplied to a switched capacitor circuit. The switched capacitor circuit has a differential configuration. The switched capacitor circuit includes an input capacitor for charging an input voltage and a reference capacitor for charging the reference voltage. The input capacitor and the reference capacitor are separately disposed. The fluctuation suppression circuit includes an electric charge supply circuit. The electric charge supply circuit generates an offset electric charge by adopting a predetermined offset voltage, for offsetting a charged or discharged electric charge generated in the switched capacitor circuit, and supplies the offset electric charge to two reference input nodes, which are supplied with the reference voltage, in the switched capacitor circuit.

According to such a configuration, it is possible to suppress the fluctuation of the reference voltage supplied to the switched capacitor circuit without implementing a countermeasure such as the addition of decoupling capacitors for widening the bandwidth of the amplifier. Therefore, it is possible to attain the effects such as enhancing the precision of the circuit, the reduction of the number of components, the reduction of consumption current, the suppression of interference, and noise suppression. In this situation, the switched capacitor circuit is a discrete-type configuration in which the input capacitor and the reference capacitor are independently disposed. Therefore, it is not necessary to consider the charging amount depending on the input in the generation of the offset electric charge in the electric charge supply circuit.

In this situation, since the switched capacitor circuit is a differential configuration, one-time operation, in other words, a charged electric charge or a discharged electric charge generated in one cycle (in other words, the consumption charge) become obvious. Therefore, it is possible that the electric charge supply circuit suppresses the fluctuation of the reference voltage with higher precision by generating the offset electric charge based on the electric charge during discharging and charging determined according to the configuration of the switched capacitor circuit. In other words, the electric charge during discharging and charging is a known value.

According to the above aspect of the present disclosure, the electric charge supply circuit supplies the offset electric charge at a timing identical to the timing during which the charging and discharging of the charge occur in the switched capacitor circuit. Since it is possible to suppress the fluctuation of the reference voltage at one-time operation, in other words, at every cycle, the effect such as enhancement of the response to one-time settling can be attained.

According to the above aspect of the present disclosure, the electric supply charge circuit generates the offset electric charge by adopting the offset voltage having a constant voltage value. As described above, the electric charge during discharging and charging in one-time operation in the switched capacitor circuit is a known value. In this situation where the offset voltage is set to a constant voltage value according to the charge in discharging and charging as a known value, it is possible to suppress the fluctuation of the reference voltage with higher precision. According to the configuration, the electric charge supply circuit may be a relatively simple configuration without having a configuration such as a DAC for varying the differential voltage VREP according to the electric charge during discharging and charging. It is possible to attain the effect in simplifying the circuitry configuration.

Hereinafter, multiple embodiments will be described with reference to the drawings. Hereinafter, in the respective embodiments, substantially the same configurations are denoted by identical symbols, and repetitive description will be omitted.

### First Embodiment

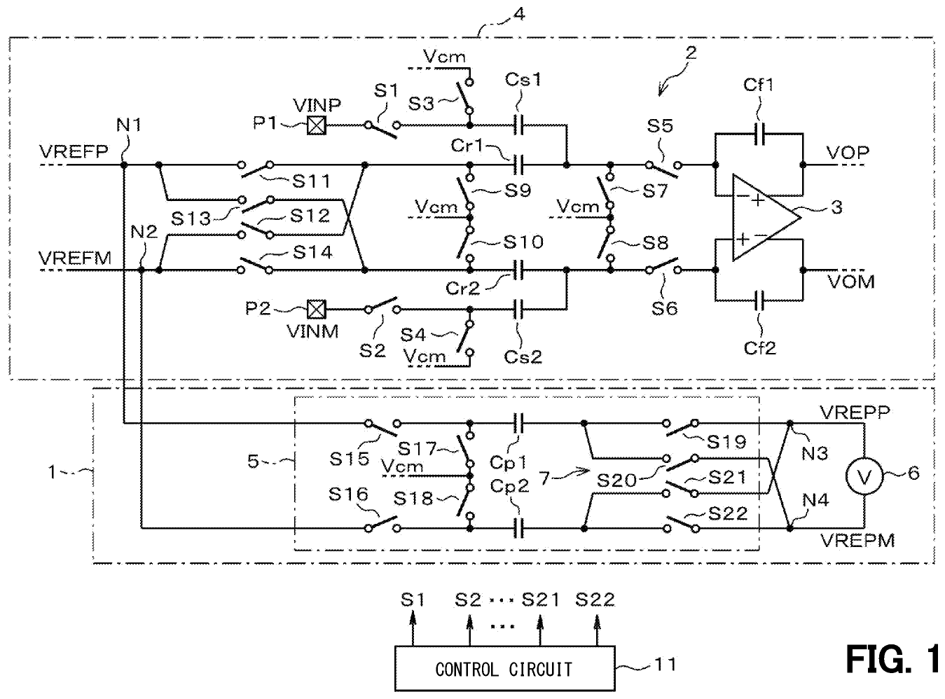

Hereinafter, the first embodiment will be described with reference to FIG. 1 to FIG. 3

A fluctuation suppression circuit 1 illustrated in FIG. 1 is a circuit that suppresses the fluctuation of reference voltages VREFP, VREFM supplied to a switched capacitor circuit 2 included in a part of a delta-sigma analog-to-digital converter (hereinafter referred to as delta-sigma type A/D converter). The fluctuation suppression circuit 1 may be applied to, for example, a battery monitoring integrated circuit for monitoring a battery installed in a vehicle. The A/D converter may also be referred to as an ADC in the following. With regard to the reference voltages VREFP, VREFM in the following, in a situation where there is no necessary to differentiate the reference voltages VREFP and VREFM, both of the reference voltages VREFP and VREFM are collectively referred to as the reference voltage VREF in the following. The switched capacitor circuit 2 has a differential configuration, and is provided for, for example, a differential-output operational amplifier 3 and an integrator 4 as an initial-stage integrator in the delta-sigma type ADC.

The reference voltages VREFP, VREFM are provided to the integrator 4 through nodes N1, N2 corresponding to reference input nodes. The reference voltages VREFP, VREFM are generated by a reference power supply (not shown). The integrator 4 receives an input of input voltages VINP, VINM through terminals P1, P2 corresponding to signal input terminals. The common voltage of the operational amplifier 3 is set to be equal to a voltage Vcm. As illustrated in the following mathematical expression (1), the voltage Vcm is an intermediate voltage between the reference voltages VREFP and VREFM.

Vcm=(VREFP−VREFM/2) (1)

Each value of the reference voltage VREFP, the reference voltage VREFM and the voltage Vcm is a predetermined value preliminarily determined according to a specification of the battery monitoring integrated circuit.

A capacitor Cf1 is connected between an inverting input terminal and a non-inverting output terminal of the operational amplifier 3, and a capacitor Cf2 is connected between a non-inverting input terminal and an inverting output terminal of the operational amplifier 3. The capacitors Cf1 and Cf2 function as integrated capacitors. The operational amplifier 3 outputs differential voltages VOP, VOM respectively from the non-inverting output terminal and the inverting output terminal. The differential voltages VOP, VOM are voltages representing integrated result obtained by the integrator 4.

The switched capacitor circuit 2 includes capacitors Cs1, Cs2, Cr1, Cr2, and switches S1 to S14. The capacitors Cs1, Cs2 formed as a pair in the differential configuration are provided for charging the input voltages VINP, VINM, and correspond to input capacitors. Capacitors Cs1 and Cs2 have the identical capacitance value Cs. The “identical capacitance value” in the present application does not only refer to a situation where the capacitance values are exactly identical, but also refers to a situation where there is a slight difference in the capacitance values as long as an advantageous effect is attained. With regard to the capacitors Cs1, Cs2 in the following, in a situation where there is no necessary to differentiate the capacitors Cs1 and Cs2, both of the capacitors Cs1 and Cs2 are collectively referred to as the capacitor Cs in the following.

The switch S1 is connected between a first end of the capacitor Cs1 and the terminal P1, and the switch S2 is connected between a first end of the capacitor Cs2 and the terminal P2. The voltage Vcm may be applied to the respective first ends of the capacitors Cs1, Cs2 through the switches S3, S4. A second end of the capacitor Cs1 is connected to the inverting input terminal of the operational amplifier 3 through the switch S5, and a second end of the capacitor Cs2 is connected to the non-inverting input terminal of the operational amplifier 3 through the switch S6. The voltage Vcm may be applied to the respective second ends of the capacitors Cs1, Cs2 through the switches S7, S8.

The capacitors Cr1, Cr2 formed as a pair in the differential configuration are provided for charging the reference voltages VREFP, VREFM, and correspond to reference capacitors. The capacitors Cr1 and Cr2 have the identical capacitance value Cs. The capacitance value Cr is a predetermined value preliminarily determined based on the resolution of the ADC determined according to, for example, the specification of the battery monitoring integrated circuit. With regard to the capacitors Cr1, Cr2 in the following, in a situation where there is no necessary to differentiate the capacitors Cr1 and Cr2, both of the capacitors Cr1 and Cr2 are collectively referred to as the capacitor Cr in the following.

The voltage Vcm may be applied to the respective first ends of the capacitors Cr1, Cr2 through the switches S9, S10. A first end of the capacitor Cr1 is connected to the node N1 through the switch S11, and is connected to the node N2 through the switch S12. A first end of the capacitor Cr2 is connected to the node N1 through the switch S13, and is connected to the node N2 through the switch S14.

The respective second ends of the capacitors Cr1, Cr2 are connected to the respective second ends of the capacitors Cs1, Cs2. In other words, the second end of the capacitor Cr1 is connected to the inverting input terminal of the operational amplifier 3 through the switch S5, and a second end of the capacitor Cr2 is connected to the non-inverting input terminal of the operational amplifier 3 through the switch S6. The voltage Vcm may be applied to the respective first ends of the capacitors Cr1, Cr2 through the switches S7, S8. As described above, the switched capacitor circuit 2 is a discrete-type configuration in which the capacitor Cs as an input capacitor and the capacitor Cr as the reference capacitor are independently disposed.

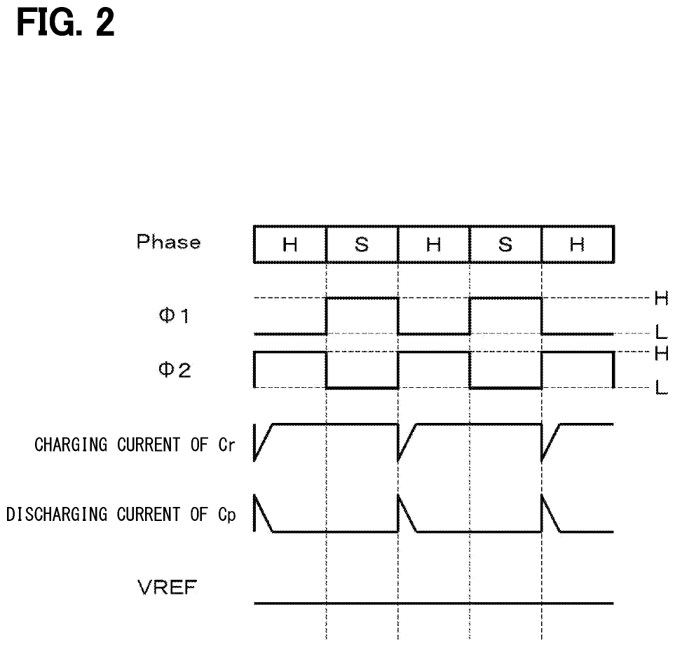

Each of the switches S1 to S14 includes, for example, a MOSFET, and each of the switches S1 to S14 is turned on or off by a control circuit 11. The switches S1, S2, S7 to S10 are collectively referred to as a first switch, and the switches S3 to S6 are collectively referred to as a second switch. The first switch and the second switch are turned on and off complementarily. As illustrated in FIG. 2, a signal ϕ1 controls the first switch to turn on or off, and a signal ϕ2 controls the second switch to turn on or off. The signals ϕ1 and ϕ2 are binary signals, and have opposite phases.

Each of the switches is turned on when the signals ϕ1 and ϕ2 have a high level, and is turned off when the signals ϕ1 and ϕ2 have a low level. In FIG. 2 and the like, the high level of the binary signal is represented by “H”, and the low level of the binary signal is represented by “L”. The period during which the signal ϕ1 is at the high level corresponding to a sampling period during which a sampling operation for charging the capacitor Cs in the switched capacitor circuit 2 is executed. The period during which the signal ϕ2 is at the high level corresponding to a holding period during which a holding operation for holding or maintaining the charges stored in capacitor Cs in the switched capacitor circuit 2 is executed. In FIG. 2 and the like, the sampling period is represented by Phase “S” and the holding period is represented by Phase “H”.

The switches S11 to S14 are included in a 1-bit D/A converter in the delta-sigma type ADC. In the following, the D/A converter may also referred to as a DAC. The switches S11 to S14 are turned off in a steady basis during the sampling period, and turned on or off according to a DAC value as a digital value input to the DAC during the holding period. The DAC value is, for example, a binary value having “1” and “−1” or a binary value having “1” and “0”, and the DAC value is generated by the control circuit 11.

For example, the switches S11, S14 are turned on and the switches S12, S13 are turned off, in a situation where the DAC value is “1”. For example, the switches S11, S14 are turned off and the switches S12, S13 are turned on, in a situation where the DAC value is “−1”. The switches S11, S14 and the switches S12, S13 are complementarily turned on or off. Since the switches S11 to S14 are controlled to turn on or off, the charged electric charge or the discharged electric charge in the switched capacitor circuit 2 is generated in the holding operation. As illustrated in FIG. 2, the charging current of the capacitor Cr indicates a relatively large value immediately after the start of the holding period, and then the charging current converges to zero.

In the switched capacitor circuit 2, the reference voltage VREF transiently fluctuates through the charging and discharging of the capacitor Cr. It is possible that the fluctuation suppression circuit 1 suppresses the fluctuation of the reference voltage VREF. The fluctuation suppression circuit 1 includes an electric charge supply circuit 5 and a voltage supply 6 having a differential configuration. The electric charge supply circuit 5 generates an offset electric charge for offsetting the charged electric charge or the discharged electric charge generated in the switched capacitor circuit 2, and the offset electric charge is supplied to the nodes N1, N2.

The voltage supply 6 is a replica reference power supply for generating a voltage similar to the reference power supply (not shown) to generate the reference voltage VREF. In a situation where a circuit for generating a voltage similar to the reference voltage is already present in the battery monitoring IC, the circuit may also function as the voltage supply 6. The voltage supply 6 outputs the differential voltages VREPP, VREPM through the respective nodes N3, N4. In this situation, the differential voltages VREPP, VREFM are predetermined voltage values which are preset. With regard to the differential voltages VREPP, VREPM in the following, in a situation where there is no necessary to differentiate the differential voltages VREPP and VREPM, both of the differential voltages VREPP and VREPM are collectively referred to as the differential voltage VREP in the following. The electric charge supply circuit 5 generates the offset electric charge by adopting the differential voltage VREP. Therefore, the differential voltage VREP corresponds to a voltage for offset or an offset voltage. The nodes N3, N4 correspond to an offset node provided by the offset voltage.

The capacitors Cp1, Cp2 formed as a pair in the differential configuration are charged or discharged through the differential voltage VREP, and correspond to an offset capacitor. The capacitors Cp1, Cp2 have an identical capacitance value Cp. With regard to the capacitors Cp1, Cp2 in the following, in a situation where there is no necessary to differentiate the capacitors Cp1 and Cp2, both of the capacitors Cp1 and Cp2 are collectively referred to as the capacitor Cp in the following. The capacitance value Cp and the respective voltage values of the differential voltages VREPP, VREPM are set to values to attain an advantageous effect of suppressing the fluctuation of the reference voltage VREF, according to the capacitance value Cr and the respective voltage values of the reference voltage VREFP, VREFM.

The switch S15 is connected between a first end of the capacitor Cp1 and the node N1, and the switch S16 is connected between a first end of the capacitor Cp2 and the node N2. The switch S15 connects or disconnects the capacitor Cp1 and the node N1, and corresponds to the first offset switch. The switch S16 connects or disconnects the capacitor Cp2 and the node N2, and corresponds to the second offset switch. The voltage Vcm may be applied to the respective first ends of the capacitors Cp1, Cp2 through the switches S17, S18.

A second end of the capacitor Cp1 is connected to the node N3 through the switch S19, and is connected to the node N4 through the switch S20. A second end of the capacitor Cp2 is connected to the node N3 through the switch S21, and is connected to the node N4 through the switch S22. In other words, the switches S19, S21 respectively connect or disconnect the node N3 and two respective capacitors Cp1, Cp2. In other words, the switches S20, S22 respectively connect or disconnect between the node N4 and two respective capacitors Cp1, Cp2. The switch circuit 7 charges and discharges two capacitors Cp1, Cp2 with the differential voltages VREPP, VREPM through the switches S19 to S22.

Each of the switches S15 to S22 includes, for example, a MOSFET, and each of the switches S15 to S22 is turned on or off by the control circuit 11. The switches S17 to S19, S22 are turned on or off by the control through the signal ϕ1, as similar to the first switch in the switched capacitor circuit 2. The switches S15, S16, S20, S21 are turned on or off by the control through the signal ϕ2, as similar to the second switch in the switched capacitor circuit 2.

Since the switches S15 to S22 are turned on or off through the control, the electric charge supply circuit 5 supplies the offset electric charge during the holding operation of the switched capacitor circuit 2. As illustrated in FIG. 2, the discharging current of the capacitor Cr indicates a relatively large value immediately after the start of the holding period, and then the charging current converges to zero. In this situation, the electric charge supply circuit 5 supplies the offset electric charge at a timing identical to the timing during which the charged electric charge or the discharged electric charge generated in the switched capacitor circuit 2. As illustrated in FIG. 2, the timing of a change in the charging current of the capacitor Cr and the timing of a change in the discharging current of the capacitor Cp coincide with each other, and the charging operation of the capacitor Cr and the discharging operation of the capacitor Cp are made to be in the identical phase.

According to the above configuration, the condition for attaining the maximum effect of suppressing the fluctuation of the reference voltage VREF is described. Although the charging and discharging of electric charges at the reference voltage VREFP side is described as an example, it may also be applied to the reference voltage VREFM side. In this situation, the charge QREFP for charging the capacitor Cr and the charge QREPP of discharging the capacitor Cp are respectively represented by the following mathematical expressions (2) and (3).

QREF=Cr(VREFP−Vcm) (2)

QREP=Cp(VREFP−VREPP)−Cr(Vcm−VREPM) (3)

According to the above configuration, in a situation where the charging current of the capacitor Cr coincides with the discharging current of the capacitor Cp, it is possible to completely suppress the fluctuation of the reference voltage VREF. In other words, in a situation where the following mathematical expression (4) is satisfied, it is possible to completely suppress the fluctuation of the reference voltage VREF.

QREF+QREP=0 (4)

In order to satisfy the relation of the mathematical expression (4), in a situation where the respective voltage values of the differential voltage VREPP, VREPM and the capacitance value Cp are set, it is possible to completely suppress the fluctuation of the reference voltage VREF. As an example for setting the voltage value and the capacitance value, as illustrated in the following mathematical expressions (5) to (7), it is considered to set the respective voltage values of the differential voltages VREPP, VREPM to be equal to the respective voltage values of the reference voltages VREFP, VREFM.

VREFP=VREPP (5)

VREFM=VREPM (6)

Cr=Cp (7)

In a situation of setting such voltage values and a capacitance value, the relation of the mathematical expression (4) is satisfied, and it is possible to completely suppress the fluctuation of the reference voltage VREF.

According to the present embodiment described above, the following effects can be attained.

In the fluctuation suppression circuit 1 according to the present embodiment, the electric charge supply circuit 5 generates the offset electric charge for offsetting the charged electric charge or the discharged electric charge generated in the switched capacitor 2 by adopting the differential voltage VREP. According to such a configuration, it is possible to suppress the fluctuation of the reference voltage VREF supplied to the switched capacitor circuit 2 without executing a countermeasure such as the addition of decoupling capacitors for widening the bandwidth of the amplifier. Therefore, it is possible to attain the effects such as enhancing the precision of the circuit, the reduction of the number of components, the reduction of consumption current, the suppression of interference, and noise suppression.

In this situation, the switched capacitor circuit 2 is a discrete-type configuration in which the capacitor Cs as an input capacitor and the capacitor Cr as the reference capacitor are independently disposed. Therefore, it is not necessary to consider the charging amount depending on the input in the generation of the offset electric charge in the electric charge supply circuit 5. In this situation, since the switched capacitor circuit 2 is a differential configuration, one-time operation, in other words, the electric charge for charging and the electric charge for discharging generated in one cycle (in other words, the consumption electric charge) become obvious. Therefore, it is possible that the electric charge supply circuit 5 suppresses the fluctuation of the reference voltage VREF with higher precision by generating the offset electric charge based on, the charge during discharging and charging determined according to the configuration of the switched capacitor circuit 2, in other words, a known value.

The electric charge supply circuit 5 supplies the offset electric charge at a timing identical to the timing during which the charged electric charge or the discharged electric charge is generated in the switched capacitor circuit 2. Since it is possible to suppress the fluctuation of the reference voltage VREF at one-time operation, in other words, at every cycle, the effect such as enhancement of the response to one-time settling can be attained. The following describes the effect of enhancing the response to the settling according to the present embodiment by introducing the configuration without the fluctuation suppression circuit 1 as a comparative example.

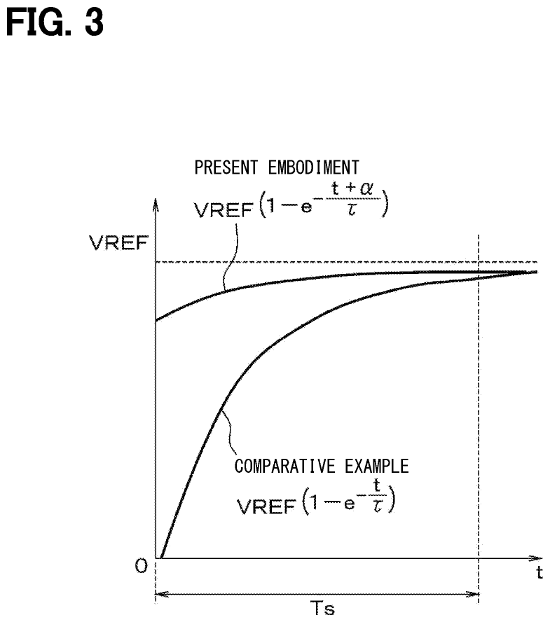

In this situation, the voltage value of the differential voltage VREP does not completely coincide with the voltage value of the reference voltage VREF. For example, a difference of 0.2% occurs. In this situation, “target settling difference<0.1 mV” is set. As illustrated in FIG. 3, the voltage value of the reference voltage VREF at the start of the sampling period Ts is closer to a steady-state value in the present embodiment; however, the voltage value of the reference voltage VREF at the start of the sampling period Ts is nearly zero. This situation is caused by the operation of the electric charge supply circuit 5 in the fluctuation suppression circuit 1.

According to the present embodiment, even in a situation where there is some error in the voltage value of the differential voltage VREP, the settling is completed earlier than in the comparative example. In the comparative example and the present embodiment, the respective reference voltages VREF in the sampling period are represented by the following mathematical expressions (8), (9). However, “t” represents time, “τ” represents an RC time constant that depends on the on-resistance of the switch and the capacitance value Cs, and “α” represents the enhancement effect of “τ” by in-phase configuration.

$$\begin{matrix}VREF ( 1 - {e}^{- \frac{t + α}{τ}} ) & ( 8 ) \\ VREF ( 1 - {e}^{- \frac{t}{τ}} ) & ( 9 )\end{matrix}$$

For example, in a situation where the time constant is required to be set at “10τ<Ts” in the comparative example, it may be set at “4τ<Ts” in the present embodiment. According to the present embodiment, the speed of settling can be enhanced about 2.5 times in terms of the time constant ratio as compared with the comparative example.

The supply charge circuit 5 generates the offset electric charge by adopting the differential voltage VREP having a constant voltage value. As described above, the electric charge during discharging and charging in the one-time operation in the switched capacitor circuit 2 is a known value. In this situation where the differential voltage VREP is set to a constant voltage value according to the charge in discharging and charging as a known value, it is possible to suppress the fluctuation of the reference voltage VREF with higher precision. According to the configuration, the electric charge supply circuit 5 may be a relatively simple configuration without having a configuration such as a DAC for varying the differential voltage VREP according to the electric charge in discharging and charging. It is possible to attain the effect in simplifying the circuitry configuration.

The switched capacitor circuit 2 has a discrete-type configuration as described above. The switched capacitor circuit 2 executes the sampling operation for charging the capacitor Cs and the holding operation for maintaining or holding the charge stored in the capacitor Cs through the sampling operation. The electric charge supply circuit 5 supplies the offset electric charge during the holding operation. The fluctuation suppression circuit 1 according to the present embodiment may be applied in a discrete-type VREF half-speed configuration.

### Second Embodiment

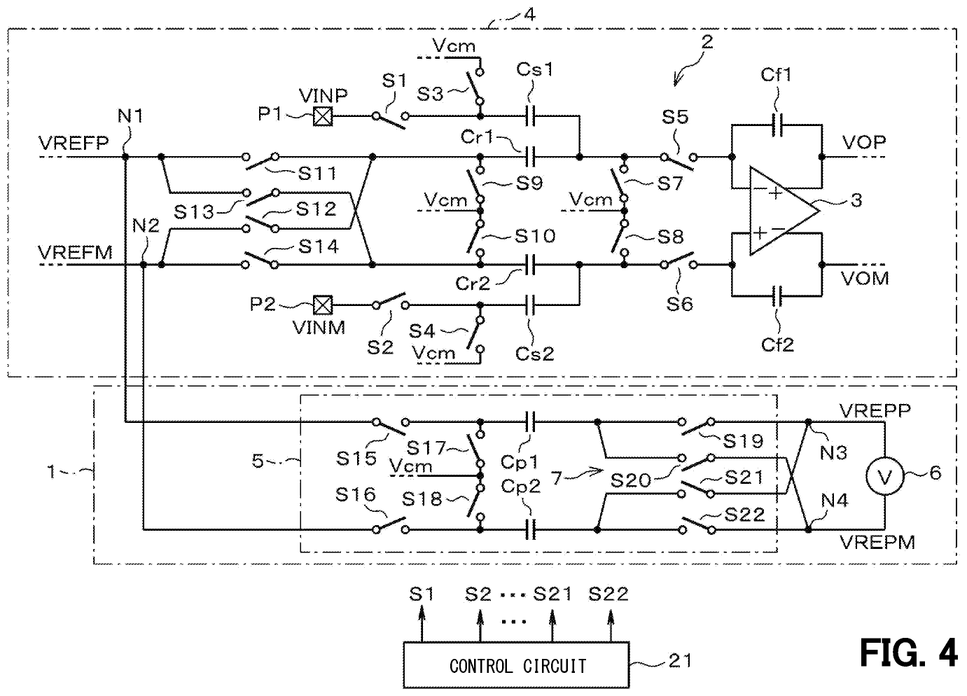

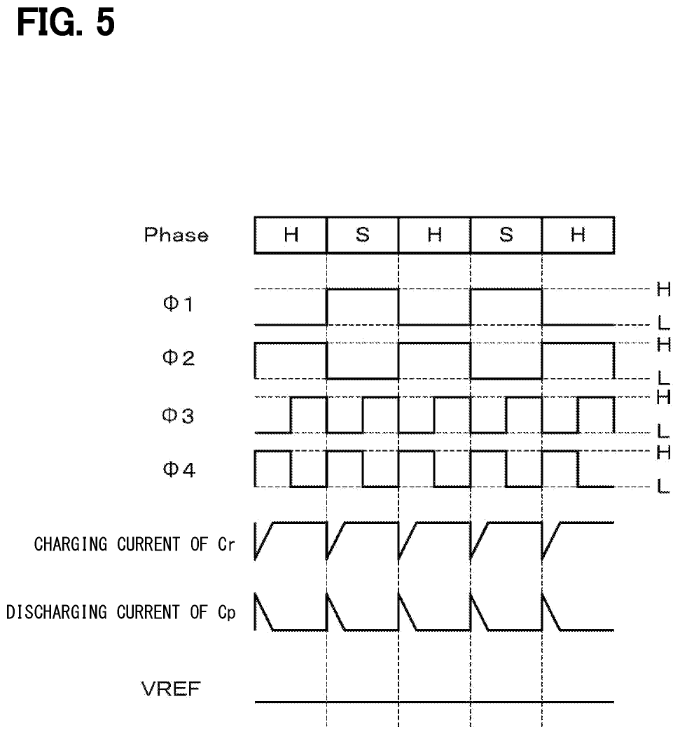

The following describes a second embodiment with reference to FIGS. 4, 5.

As illustrated in FIG. 4, in the second embodiment, a control circuit 21 is provided in replacement of the control circuit 11 in the first embodiment. The switches S11 to S14 is turned on or off according to a DAC value in both of the sampling period and the holding period.

During the sampling period, the switches S11, S14 are turned off and the switches S12, S13 are turned on in a situation where the DAC value is “1”; and the switches S11, S14 are turned on and the switches S12, S13 are turned off in a situation where the DAC value is “−1”. During the holding period, the switches S11, S14 are turned on and the switches S12, S13 are turned off in a situation where the DAC value is “1”; and the switches S11, S14 are turned off and the switches S12, S13 are turned on in a situation where the DAC value is “−1”.

Since the switches S11 to S14 are controlled to turn on or off, the charged electric charge or the discharged electric charge in the switched capacitor circuit 2 is generated in both of the holding operation and the sampling operation. As illustrated in FIG. 5, the charging current of the capacitor Cr indicates a relatively large value immediately after the start of the holding period and the sampling period, and then the charging current converges to zero.

The control circuit 21 controls the switches S15 to S22 in the electric charge supply circuit 5 as described in the following. The switches S17 to S19, S22 are collectively referred to as a third switch, and the switches S15, S16, S20, S21 are collectively referred to as a fourth switch. The third switch and the fourth switch are turned on and off complementarily. As illustrated in FIG. 5, a signal ϕ3 controls the third switch to turn on or off, and a signal ϕ4 controls the fourth switch to turn on or off. The signals ϕ3 and ϕ4 are binary signals, and have opposite phases. Further, the period or cycle of the signals ϕ3 and ϕ4 is half the period or cycle of the signals ϕ1 and ϕ2. In other words, the fluctuation suppression circuit 1 operates at multiple times of speed as compared with the switched capacitor circuit 2.

Since the switches S15 to S22 are turned on or off, the electric charge supply circuit 5 supplies the offset electric charge during the holding operation and the sampling period of the switched capacitor circuit 2. As illustrated in FIG. 5, the discharging current of the capacitor Cp indicates a relatively large value immediately after the start of the holding period and the sampling period, and then the charging current converges to zero.

As similar to the first embodiment, the electric charge supply circuit 5 supplies the offset electric charge at a timing identical to the timing during which the discharged electric charge or the charged electric charge is generated in the switched capacitor circuit 2. As illustrated in FIG. 5, the timing of a change in the charging current of the capacitor Cr and the timing of a change in the discharging current of the capacitor Cp coincide with each other, and the charging operation of the capacitor Cr and the discharging operation of the capacitor Cp are made to be in the identical phase.

Therefore, according to the present embodiment, the same effects as in the first embodiment are attained. The switched capacitor circuit 2 is a discrete-type configuration. The switched capacitor circuit 2 has a configuration where the electric charges in discharging and charging are generated in both of the sampling and holding operations. In other words, the switched capacitor circuit 2 is a discrete-type VREF multiple-speed configuration. The electric charge supply circuit 5 supplies the offset electric charge during the holding operation and the sampling operation. The fluctuation suppression circuit 1 according to the present embodiment may be applied in a discrete-type VREF multiple-speed configuration.

### Third Embodiment

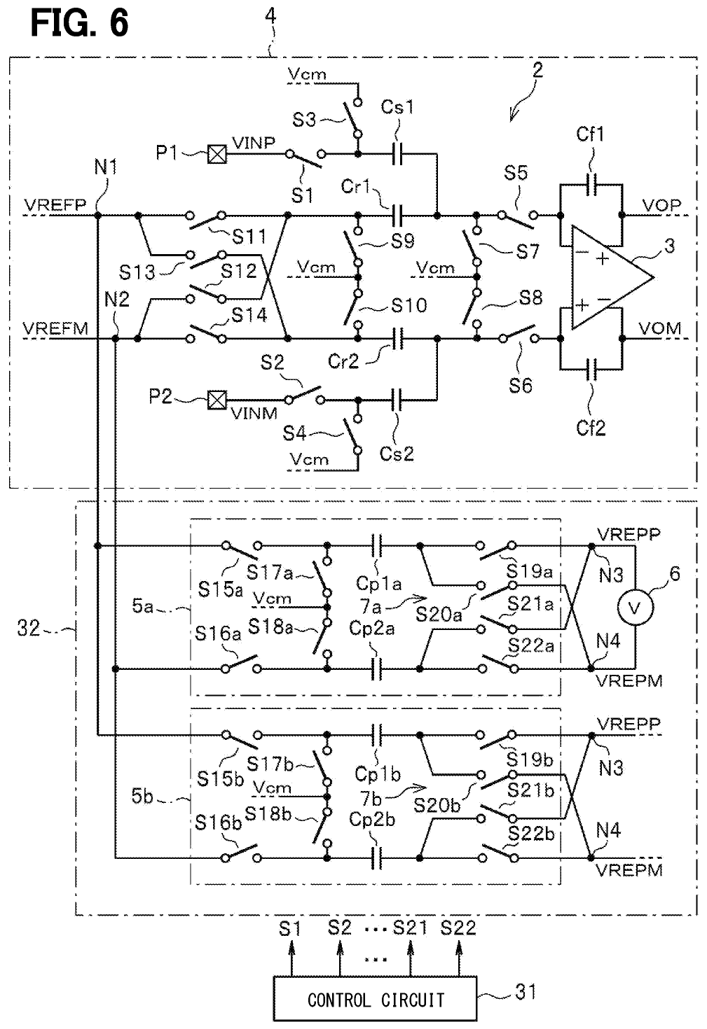

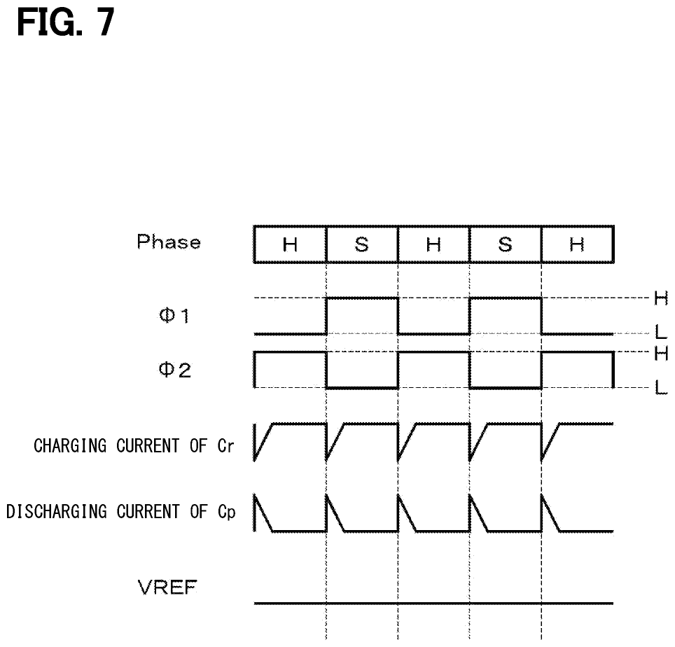

The following describes a third embodiment with reference to FIGS. 6, 7.

As illustrated in FIG. 6, in the third embodiment, a control circuit 31 is provided in replacement of the control circuit 11 in the first embodiment. The fluctuation suppression circuit 32 in the third embodiment has an electric charge supply circuit 5 having two systems (may also be referred to as a dual system). In the following, the first system of the electric charge supply circuit 5 is referred to as the first electric charge supply circuit 5a, and the second system of the electric charge supply circuit 5 is referred to as the second electric charge supply circuit 5b. Additionally, “a” is appended to the reference numeral of a component included in the first electric charge supply circuit 5a, and “b” is appended to the reference numeral of a component included in the second electric charge supply circuit 5b. The switches S11 to S14 is turned on or off according to a DAC value in both of the sampling period and the holding period, as similar to the second embodiment.

The control circuit 31 controls the switches S15a to S22a in the electric charge supply circuit 5 as described in the following. The switches S17a to S19a, S22a are turned on or off by the control through the signal ϕ2, as similar to the second switch in the switched capacitor circuit 2. The switches S15a, S16a, S20a, S21a are turned on or off by the control through the signal ϕ1, as similar to the first switch in the switched capacitor circuit 2. Since the switches S15 to S22 are turned on or off, the electric charge supply circuit 5a supplies the offset electric charge during the sampling operation of the switched capacitor circuit 2.

The control circuit 31 controls the switches 515b to S22b in the second electric charge supply circuit 5 as described in the following. The switches 517b to 519b, S22b are turned on or off by the control through the signal ϕ1, as similar to the first switch in the switched capacitor circuit 2. The switches 515b, 516b, S20b, S21b are turned on or off by the control through the signal ϕ2, as similar to the second switch in the switched capacitor circuit 2. Since the switches 515b to S22b are turned on or off, the second electric charge supply circuit 5b supplies the offset electric charge during the holding operation of the switched capacitor circuit 2.

In other words, the fluctuation suppression circuit 32 shifts the respective phases of the first electric charge supply circuit 5a and the second electric charge supply circuit 5b to be a half cycle apart from each other. As illustrated in FIG. 7, as a result, the discharging current of the capacitor Cp indicates a relatively large value immediately after the start of the holding period and the sampling period, and then the charging current converges to zero. As similar to the first embodiment, the electric charge supply circuits 5a, 5b respectively supply the offset electric charge at a timing identical to the timing during which the discharged electric charge or the charged electric charge is generated in the switched capacitor circuit 2. As illustrated in FIG. 7, the timing of a change in the charging current of the capacitor Cr and the timing of a change in the discharging current of the capacitor Cp coincide with each other, and the charging operation of the capacitor Cr and the discharging operation of the capacitor Cp are made to be in the identical phase.

Therefore, according to the present embodiment, the same effects as in the first embodiment are attained. The switched capacitor circuit 2 is a discrete-type configuration. The switched capacitor circuit 2 has a configuration where the electric charges during discharging and charging are generated in both of the sampling and holding operations. In other words, the switched capacitor circuit 2 is a discrete-type VREF multiple-speed configuration. The electric charge supply circuit 5 supplies the offset electric charge during the holding operation and the sampling operation. The fluctuation suppression circuit 1, as similar to the second embodiment, may be applied in a discretetype VREF multiple-speed configuration.

### Fourth Embodiment

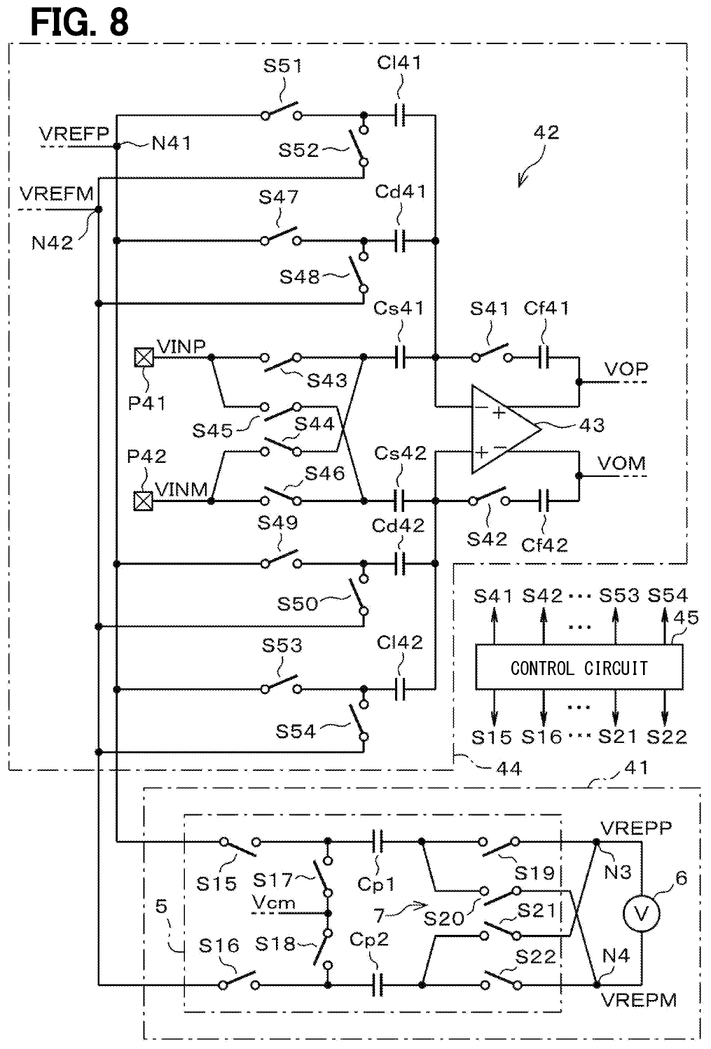

The following describes a fourth embodiment with reference to FIG. 8.

As shown in FIG. 8, the fluctuation suppression circuit 41 according to the present embodiment suppresses the fluctuation of the reference voltages VREPF, VREFM supplied to the switched capacitor circuit 42, and has a configuration similar to the fluctuation suppression circuit 1 in, for example, the first embodiment. The switched capacitor circuit 42 has a differential configuration, and is provided for, for example, a differential-output operational amplifier 43 and an integrator 44 as an initial-stage integrator in the delta-sigma type ADC.

The reference voltages VREFP, VREFM are provided to the integrator 44 through nodes N41, N42 corresponding to reference input nodes. The integrator 44 receives an input of input voltages VINP, VINM through terminals P41, P42 corresponding to signal input terminals. In this situation, the input voltages VINP, VINM are, for example, in a 5V range, while the internal circuits are all operated at 3V. Therefore, the integrator 44 includes a level shift circuit that executes a level shift for lowering a voltage from 5V to 3V.

A series circuit having the switch S41 and the capacitor Cf41 is connected between the inverting input terminal and the non-inverting output terminal of the operational amplifier 43, and a series circuit having the switch S42 and the capacitor Cf42 is connected between the non-inverting input terminal and the inverting output terminal of the operational amplifier 43. The capacitors Cf41 and Cf42 function as integrated capacitors. The operational amplifier 43 outputs differential voltages VOP, VOM respectively from the non-inverting output terminal and the inverting output terminal. The differential voltages VOP, VOM are voltages representing integrated result obtained by the integrator 44.

The switched capacitor circuit 42 includes the capacitors Cs41, Cs42, Cd41, Cd42, Cl41, Cl42 and switches S43 to S54. The capacitors Cs41, Cs42, as similar to Cs1, Cs2, formed as a pair in the differential configuration are provided for charging the input voltages VINP, VINM, and correspond to input capacitors. Capacitors Cs41 and Cs42 have the identical capacitance value Cs.

A first end of the capacitor Cs41 is connected to the terminal P41 through the switch S43, and is connected to the terminal P42 through the switch S44. A second end of the capacitor Cs42 is connected to the terminal P41 through the switch S45, and is connected to the terminal P42 through the switch S46. A second end of the capacitor Cs41 is connected to the inverting input terminal of the operational amplifier 43, and a second end of the capacitor Cs42 is connected to the non-inverting input terminal of the operational amplifier 43.

The capacitors Cd41, Cd42 formed as a pair in the differential configuration are provided for charging the reference voltages VREFP, VREFM, and correspond to reference capacitors. Capacitors Cd41 and Cd42 have the identical capacitance value Cd. The capacitance value Cd is a predetermined value preliminarily determined according to, for example, the specification of the battery monitoring integrated circuit. With regard to the capacitors Cd41, Cd42 in the following, in a situation where there is no necessary to differentiate the capacitors Cd41 and Cd42, both of the capacitors Cd41 and Cd42 are collectively referred to as the capacitor Cd in the following.

A first end of the capacitor Cd41 is connected to the node N41 through the switch S47, and is connected to the node N42 through the switch S48. A first end of the capacitor Cd42 is connected to the node N41 through the switch S49, and is connected to the node N42 through the switch S50. A second end of the capacitor Cd41 is connected to the inverting input terminal of the operational amplifier 43, and a second end of the capacitor Cd42 is connected to the non-inverting input terminal of the operational amplifier 43.

The capacitors Cl41, Cl42 formed as a pair in the differential configuration are provided for charging the reference voltages VREFP, VREFM, and correspond to reference capacitors. Capacitors Cl41 and Cl42 have the identical capacitance value Cl. The capacitance value CI is a predetermined value preliminarily determined according to, for example, the specification of the battery monitoring integrated circuit. With regard to the capacitors Cl41, Cl42 in the following, in a situation where there is no necessary to differentiate the capacitors Cl41 and Cl42, both of the capacitors Cl41 and Cl42 are collectively referred to as the capacitor CI in the following.

A first end of the capacitor Cl41 is connected to the node N41 through the switch S51, and is connected to the node N42 through the switch S52. A first end of the capacitor Cl42 is connected to the node N41 through the switch S53, and is connected to the node N42 through the switch S54. A second end of the capacitor Cl41 is connected to the inverting input terminal of the operational amplifier 43, and a second end of the capacitor Cl42 is connected to the non-inverting input terminal of the operational amplifier 43. As described above, the switched capacitor circuit 42, as similar to the switched capacitor circuit 2, is a discrete-type configuration in which the capacitor Cs as an input capacitor and the capacitors Cd, Cl as the reference capacitor are independently disposed.

The switches S41 to S54 are turned on or off by the control circuit 45. The switches S43, S46 are turned on or off by the control through the signal ϕ1, as similar to the first switch in the switched capacitor circuit 2 according to the second embodiment. The switches S44, S45 are turned on or off by the control through the signal ϕ2, as similar to the second switch in the switched capacitor circuit 2 according to the second embodiment.

The switches S47 to S50 are included in a 1-bit D/A converter in the delta-signal type ADC. The switches S47 to S50 are turned on or off according to a DAC value in both of the sampling period and the holding period, as similar to the switches S11 to S14 in the second embodiment. The switches S51 to S54 are included in a level shift circuit in the integrator 44. The switches S51 to S54 are turned on or off at the timing identical to the switches S47 to S50 included in the DAC.

However, the switches S51 to S54 are different from the switches S47 to S50, the switches S51 to S54 are controlled in a steady basis according to the level shift direction. For example, in a situation where the level is shifted in a negative direction, the switches S51, S54 are turned off and the switches S52, S53 are turned on in the sampling period during which the signal ϕ1 is turned to the high level. In addition, the switches S51, S54 are turned on and the switches S52, S53 are turned off in the holding period during which the signal ϕ2 is turned to the high level.

Since the switches S47 to S54 are controlled to turn on or off, the charging or discharging of the charges in the switched capacitor circuit 42 occurs in both of the holding operation and the sampling operation. As illustrated in FIG. 5, as similar to the charging current of the capacitor Cr in the second embodiment illustrated in FIG. 5, the charging current of the capacitor Cd and the charging current of the capacitor CI respectively indicate a relatively large value immediately after the start of the holding period and the sampling period, and then the charging current converges to zero.

The control circuit 45 controls the switches S15 to S22 in the electric charge supply circuit 5 to turn on or off, as similar to the control circuit 21 in the second embodiment. In other words, the fluctuation suppression circuit 41 operates at multiple times of speed as compared with the switched capacitor circuit 42. Since the switches S15 to S22 are turned on or off, the electric charge supply circuit 5 supplies the offset electric charge during the holding operation and the sampling period of the switched capacitor circuit 42. As similar to the charging current of the capacitor Cp in the second embodiment illustrated in FIG. 5, the charging current of the capacitor Cp indicates a relatively large value immediately after the start of the holding period and the sampling period, and then the charging current converges to zero.

In this situation, the electric charge supply circuit 5 supplies the offset electric charge at a timing identical to the timing during which the charged electric charge or the discharged electric charge is generated in the switched capacitor circuit 42. The timing of a change in the charging current of the capacitor Cd and the timing of a change in the discharging current of the capacitor Cp coincide with each other, and the charging operation of the capacitor Cd and the discharging operation of the capacitor Cp are made to be in the identical phase.

According to the fluctuation suppression circuit 41 in the present embodiment as described above, it is possible to suppress the fluctuation of the reference voltage VREF supplied to the switched capacitor circuit in a part of the level shift circuit. In this situation, in the switched capacitor circuit 42, each of the capacitor Cd near the DAC and the capacitor CI near the level shift circuit consumes the electric charges.

In the switched capacitor circuit 42, the operation timing of the DAC, in other words, the operation timing of the switches S47 to S50 and the operation timing of the level shift circuit, in other words, the operation timing of the switches S51 to S54 are identical. In the electric charge supply circuit 5 of the fluctuation suppression circuit 41, the offset electric charge, which is identical to the total amount of the charged electric charge or the discharged at the DAC and the charged electric charge or the discharged electric charge at the level shift circuit, can be supplied to the nodes N41, N42. Therefore, it is possible to suppress the fluctuation of the reference voltage VREF with enhanced precision in a situation of setting each of the capacitance values Cp and the respective voltage values of the differential voltages VREPP, VREPM.

### Fifth Embodiment

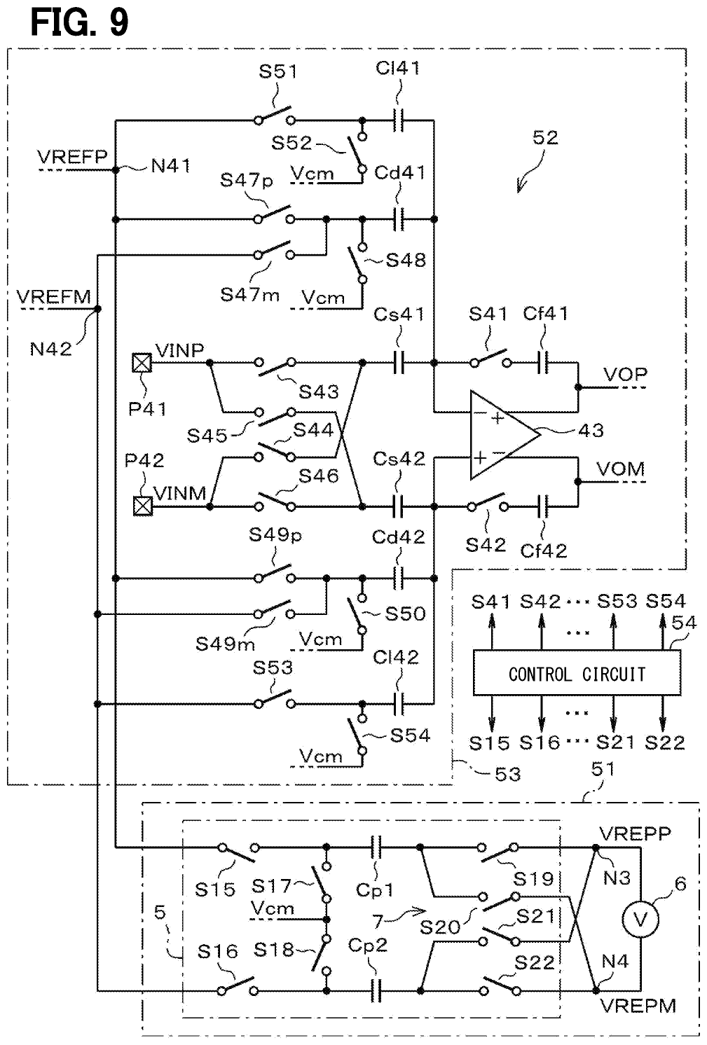

The following describes a fifth embodiment with reference to FIG. 9.

As shown in FIG. 9, the fluctuation suppression circuit 51 according to the present embodiment suppresses the fluctuation of the reference voltages VREFP, VREFM supplied to the switched capacitor circuit 52, and has a configuration similar to the fluctuation suppression circuit 1 in, for example, the first embodiment. The switched capacitor circuit 52 has a differential configuration, and is provided for, for example, a differential-output operational amplifier 53 and an integrator 54 as an initial-stage integrator in the delta sigma ADC.

The switched capacitor circuit 52 is different from the switched capacitor circuit 42 in the fourth embodiment such that the control adopts the voltage Vcm in the switched capacitor circuit 52. Therefore, the switched capacitor circuit 52 is different from the switched capacitor 42 in some structures as described in the following. The voltage Vcm may be applied to the respective first ends of the capacitors Cd41, Cd42 through the switches S48, S50.

The switches S47p, S47m are disposed in replacement of the switch S47, and the switches S49p, S49m are disposed in replacement of the switch S49. A first end of the capacitor Cd41 is connected to the node N41 through the switch S47p, and is connected to the node N42 through the switch S47m. A first end of the capacitor Cd42 is connected to the node N41 through the switch S49p, and is connected to the node N42 through the switch S49m.

The voltage Vcm may be applied to the respective first ends of the capacitors Cl41, Cl42 through the switches S52, S54. Even in this situation, the first end of the capacitor Cl41 is connected to the node N41 through the switch S51. However, in this situation, the first end of the capacitor Cl42 is connected to the node N42 through the switch S53.

The switches S41 to S54 are turned on or off by the control circuit 54. The switches S43, S46, S48, S50, S52, S54 are turned on or off by the control through the signal ϕ1, as similar to the first switch in the switched capacitor circuit 2 according to the first embodiment. The switches S44, S45, S51, S53 are turned on or off by the control through the signal ϕ2, as similar to the second switch in the switched capacitor circuit 2 according to the second embodiment. Moreover, the switches S47p, S47m, S49p, S49m, as similar to the switches S11 to S14 in the first embodiment, are turned off in a steady basis during the sampling period, and turned on or off according to the DAC value as a digital value input to the DAC during the holding period. In this situation, the level shift circuit is configured to shift the level in the negative direction.

Since the switches S47p to S54 are controlled to turn on or off, the charged electric charge or the discharged electric charge of the switched capacitor circuit 52 is generated in the holding operation. As illustrated in FIG. 5, as similar to the charging current of the capacitor Cr in the first embodiment illustrated in FIG. 2, the charging current of the capacitor Cd and the charging current of the capacitor CI respectively indicate a relatively large value immediately after the start of the holding period and the sampling period, and then the charging current converges to zero.

The control circuit 54 controls the switches S15 to S22 in the electric charge supply circuit 5 to turn on or off, as similar to the control circuit 11 in the first embodiment. Since the switches S15 to S22 are turned on or off, the electric charge supply circuit 5 supplies the offset electric charge during the holding operation of the switched capacitor circuit 52. As similar to the charging current of the capacitor Cp in the first embodiment illustrated in FIG. 2, the charging current of the capacitor Cp indicates a relatively large value immediately after the start of the holding period and the sampling period, and then the charging current converges to zero.

In this situation, the electric charge supply circuit 5 supplies the offset electric charge at a timing identical to the timing during which the charged electric charge or the discharged electric charge is generated in the switched capacitor circuit 52. The timing of a change in the charging current of the capacitors Cd and CI and the timing of a change in the discharging current of the capacitor Cp coincide with each other as similar in the first embodiment, and the charging operation of the capacitors Cd and CI and the discharging operation of the capacitor Cp are made to be in the identical phase.

According to the fluctuation suppression circuit 51 in the present embodiment as described above, it is possible to suppress the fluctuation of the reference voltage VREF supplied to the switched capacitor circuit 52 in a part of the level shift circuit, as similar to the fourth embodiment. In this situation, in the switched capacitor circuit 52, each of the capacitor Cd near the DAC and the capacitor CI near the level shift circuit consume the electric charges, as similar to the fourth embodiment.

In the switched capacitor circuit 52, the operation timing of the DAC, in other words, the operation timing of the switches S47p to S50 and the operation timing of the level shift circuit, in other words, the operation timing of the switches S51 to S54 are identical, as similar to the fourth embodiment. In the electric charge supply circuit 5 of the fluctuation suppression circuit 51, the offset electric charge, which is identical to the total amount of the charged electric charge or the discharged electric charge at the DAC and the charged electric charge or the discharged electric charge at the level shift circuit, can be supplied to the nodes N41, N42. Therefore, it is possible to suppress the fluctuation of the reference voltage VREF with enhanced precision in a situation of setting each of the capacitance values Cp and the respective voltage values of the differential voltages VREPP, VREPM.

### Other Embodiments

The present disclosure is not limited to the embodiments that have been described above and illustrated in the drawings, but can arbitrarily be modified, combined, or expanded without departing from the gist of the present disclosure.

The numerical values and the like shown in each of the above embodiments are merely examples, and the present disclosure is not limited thereto.

The fluctuation suppression circuit according to each of the above embodiments is applied to a switched capacitor circuit included in a part of the delta sigma ADC. However, the fluctuation suppression circuit in the present disclosure may also be applied to a discrete-type switched capacitor circuit having a differential configuration.

The electric charge supply circuit 5 may not be limited to the configuration shown in FIGS. 1, 4, 6, 8, and 9. The configuration may be modified as appropriate.

The fluctuation suppression circuit according to each of the above embodiments is applied to a single switched capacitor circuit. However, the fluctuation suppression circuit in the present disclosure may suppress the reference voltage supplied to plural switched capacitor circuits. In a situation where the plural switched capacitor circuits adopting the reference voltage are present, in a condition that the plural switched capacitor circuits operate at the identical timing, the electric charge supply circuit for supplying the offset electric charges identical to the total amount of the respective charged electric charges or the respective discharged electric charges at the plural switched capacitor circuits may be provided as long as the plural switched capacitor circuits operate at the identical timing. In this situation, the plural electric charge supply circuits for supplying the offset electric charge identical to the respective electric charges during discharging and charging at the plural switched capacitor circuits may be provided.

Although the present disclosure has been made in accordance with the embodiments, it is understood that the present disclosure is not limited to such embodiments and structures. The present disclosure encompasses various modifications and variations within the scope of equivalents. In addition, various combinations and configurations, as well as other combinations and configurations that include only one element, more, or less, fall within the scope and spirit of the present disclosure.

What is claimed is:

1. A fluctuation suppression circuit comprising:
an electric charge supply circuit,
wherein the fluctuation suppression circuit is configured to suppress fluctuation of a reference voltage supplied to a switched capacitor circuit having a differential configuration,
wherein the switched capacitor circuit includes an input capacitor for charging an input voltage and a reference capacitor for charging the reference voltage, and the input capacitor and the reference capacitor are separately disposed, and
wherein the electric charge supply circuit is configured to:
generate an offset electric charge by adopting a predetermined offset voltage, for offsetting a charged or discharged electric charge generated in the switched capacitor circuit; and
supply the offset electric charge to two reference input nodes, which are supplied with the reference voltage, in the switched capacitor circuit.

2. The fluctuation suppression circuit according to claim 1,
wherein the electric charge supply circuit is further configured to supply the offset electric charge at a timing identical to a timing at which the charged or discharged electric charge is generated in the switched capacitor circuit.

3. The fluctuation suppression circuit according to claim 1,
wherein the electric charge supply circuit is further configured to generate the offset electric charge by adopting the offset voltage having a voltage value being a constant value.

4. The fluctuation suppression circuit according to claim 1,
wherein the electric charge supply circuit is a differential configuration,
wherein one of the two reference input nodes is a first reference input node, and another one of the two reference input nodes is a second reference input node, and
wherein the electric charge supply circuit includes:
two offset capacitors provided as a pair in the differential configuration, one of the two offset capacitors being a first offset capacitor and another one of the two offset capacitors being a second offset capacitor;
a first offset switch configured to connect or disconnect the first offset capacitor and the first reference input node; and
a second offset switch configured to connect or disconnect the second offset capacitor and the second reference input node.

5. The fluctuation suppression circuit according to claim 4,
wherein the electric charge supply circuit further includes a switch circuit configured to charge or discharge the two offset capacitors by adopting the offset voltage,
wherein the offset voltage is supplied to two offset nodes,
wherein one of the two offset nodes is a first offset node, and another one of the two offset nodes is a second offset node, and
wherein the switch circuit includes:
a first group of switches having two switches, one of the two switches in the first group configured to connect or disconnect the first offset node and the first offset capacitor, another one of the two switches in the first group configured to connect or disconnect the first offset node and the second offset capacitor; and
a second group of switches having two switches, one of the two switches in the second group configured to connect or disconnect the second offset node and the first offset capacitor, another one of the two switches in the second group configured to connect or disconnect the second offset node and the second offset capacitor.

6. The fluctuation suppression circuit according to claim 1,
wherein the switched capacitor circuit is further configured to execute:
a sampling operation for charging the input capacitor; and
a holding operation for holding an electric charge stored in the input capacitor charged by the sampling operation,
wherein the holding operation generates the charged or discharged electric charge, and
wherein the electric charge supply circuit is further configured to supply the offset electric charge in the holding operation.

7. The fluctuation suppression circuit according to claim 1,
wherein the switched capacitor is configured to execute:
a sampling operation for charging the input capacitor; and
a holding operation for holding an electric charge stored in the input capacitor charged by the sampling operation,
wherein the sampling operation and the holding operation generate the charged or discharged electric charge, and
wherein the electric charge supply circuit is further configured to supply the offset electric charge in the holding operation and the sampling operation.

8. The fluctuation suppression circuit according to claim 7,
wherein the electric charge supply circuit includes two electric charge supply circuits,
wherein one of the two electric charge supply circuits is a first electric charge supply circuit configured to supply the offset electric charge in the sampling operation, and another one of two electric charge supply circuits is a second electric charge supply circuit configured to supply the offset electric charge in the holding operation.

9. The fluctuation suppression circuit according to claim 1,
wherein the fluctuation suppression circuit is further configured to suppress the fluctuation of the reference voltage supplied to the switched capacitor circuit included in a part of an analog-to-digital converter.

10. The fluctuation suppression circuit according to claim 1,
wherein the fluctuation suppression circuit is further configured to suppress the fluctuation of the reference voltage supplied to the switched capacitor circuit included in a part of a level shift circuit.
